(19) United States
(12) Patent Application Publication
(10) Pub. No.: US 2009/0152569 A1
(43) Pub. Date: Jun. 18, 2009

(54) LED MODULE WITH REDUCED OPERATING TEMPERATURE

(75) Inventors: Ching-Chi Cheng, Taoyuan Hsien (TW); Shang-Jin Yan, Taoyuan Hsien (TW); Chung-Tsai Huang, Taoyuan Hsien (TW); Po-Yi Lee, Taoyuan Hsien (TW)

Correspondence Address: KIRTON AND MCCONKIE, 60 EAST SOUTH TEMPLE,, SUITE 1800, SALT LAKE CITY, UT, 84111, US

(73) Assignee: DELTA ELECTRONICS, INC., Taoyuan Hsien (TW)

(21) Appl. No.: 12/037,271

(22) Filed: Feb. 26, 2008

(30) Foreign Application Priority Data
Dec. 17, 2007 (TW) 096148325

(51) Int. Cl. H01L 25/075

(52) U.S. Cl. 257/88; 257/E25.021

(57) ABSTRACT

The present invention relates to a LED module with a reduced operating temperature. The LED module includes a substrate, a plurality of LED chips, a carrier and an encapsulant layer. These LED chips are disposed on the substrate and electrically connected to the substrate and are divided into a first LED chip set and a second LED chip set. The carrier is coupled to the substrate and has a driving circuit. The driving circuit is electrically connected to the plurality of LED chips for driving operations of the plurality of LED chips. The first LED chip set and the second LED chip set emit light in an alternate lighting manner or in a combined simultaneous/alternate lighting manner so as to reduce the operating temperature of the LED module. The encapsulant layer covers the plurality of LED chips, the substrate and the carrier having the driving circuit.

### FIELD OF THE INVENTION

The present invention relates to a LED module, and more particularly to a LED module with a reduced operating temperature.

### BACKGROUND OF THE INVENTION

In recent years, light emitting diodes (LEDs) capable of emitting light with high luminance and high illuminating efficiency have been developed. In comparison with a common incandescent light, a LED has lower power consumption, long service life, and quick response speed. With the maturity of the LED technology, LEDs will replace all conventional lighting facilities. Until now, LEDs are widely used in many aspects of daily lives, such as automobile lighting devices, handheld lighting devices, backlight sources for LCDs, traffic lights, indicator board displays, and the like.

Referring to FIG. 1, a conventional LED package is schematically illustrated. The conventional LED package 1 principally includes a LED chip 11, a substrate 12 and an encapsulant layer 13. The LED chip 11 is disposed on the substrate 12 and electrically connected to the substrate 12. After the LED chip 11 is disposed on the substrate 12, the LED chip 11 and the substrate 12 are encapsulated with the encapsulant layer 13 to avoid physical damage or corrosion. Depending on the composition of the semi-conducting material used for fabricating the LED chip 11, the color of the emitted light may be varied.

As known, the LED chip 11 of the LED package 1 is driven by an external driving circuit 2, which is formed in a carrier 3. Therefore, the LED package 1 should be connected to the carrier 3 having the external driving circuit 2 before use.

Since the LED chip 11 is driven by the external driving circuit 2, excessive heat will be possibly generated during operation. The excessive heat may result in reduced illuminating efficiency. LED performance largely depends on the ambient temperature of the operating environment. In a case that the heat generated from the LED chip 11 is not quickly dissipated away, the overheating of the LED package 1 eventually leads to device failure. As a consequence, the LED cooling system with high heat-dissipating efficiency and cost-effectiveness becomes a key design criterion.

For most LED packages, there are two mechanisms for dissipating heat, i.e. an internal heat-dissipation mechanism and an external heat-dissipation mechanism. The internal heat-dissipation mechanism uses a thermal conductive body inside the LED package to remove the heat generated from the LED chip to the ambient surroundings. The external heat-dissipation mechanism uses a heat sink or a fan outside the LED package to facilitate heat radiation.

Since a great amount of heat is generated from the LED chip, the heat-dissipating effect of the internal heat-dissipation mechanism or the external heat-dissipation mechanism is usually unsatisfied. If the heat generated from the LED chip is not effectively dissipated away, the higher operating temperature may degrade the performance of the LED package. Moreover, the external heat-dissipation mechanism is detrimental to the connection and the layout of the carrier 3 and the LED package 1.

There is a need of a providing a LED module with a reduced operating temperature to obviate the drawbacks encountered from the prior art.

### SUMMARY OF THE INVENTION

It is an object of the present invention to provide a LED module with a reduced operating temperature in order to avoid the problems encountered from the conventional heat-dissipation mechanisms.

In accordance with an aspect of the present invention, there is provided a LED module with a reduced operating temperature. The LED module includes a substrate, a plurality of LED chips, a carrier and an encapsulant layer. These LED chips are disposed on the substrate and electrically connected to the substrate and are divided into a first LED chip set and a second LED chip set. The carrier is coupled to the substrate and has a driving circuit. The driving circuit is electrically connected to the plurality of LED chips for driving operations of the plurality of LED chips. The first LED chip set and the second LED chip set emit light in an alternate lighting manner or in a combined simultaneous/alternate lighting manner so as to reduce the operating temperature of the LED module. The encapsulant layer covers the plurality of LED chips, the substrate and the carrier having the driving circuit.

The above contents of the present invention will become more readily apparent to those ordinarily skilled in the art after reviewing the following detailed description and accompanying drawings, in which:

### BRIEF DESCRIPTION OF THE DRAWINGS

FIG. 1 schematically illustrates a conventional LED package;

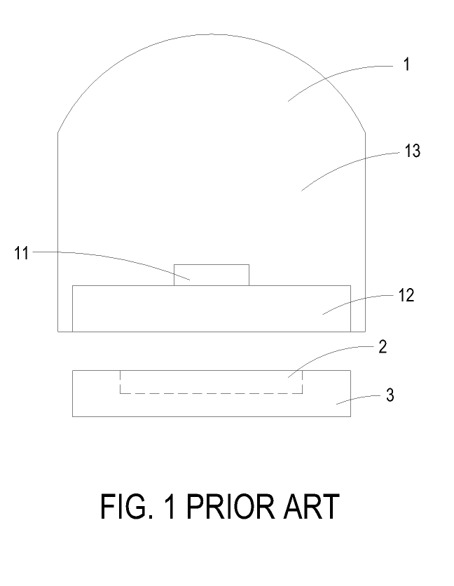

FIG. 2 is a schematic view illustrating a LED module with a reduced operating temperature according to a preferred embodiment of the present invention;

FIG. 3 is a circuit diagram illustrating an exemplary driving circuit shown in FIG. 2 according to the present invention;

FIG. 4 is a circuit diagram illustrating another exemplary driving circuit;

FIG. 5 is a characteristic plot showing the brightness and the operating temperature of a single LED chip as a function of operating time;

FIG. 6 is a graph showing the relationship between the brightness and the operating temperature of the first LED chip set and the second LED chip set as a function of operating time by an alternate lighting manner;

FIG. 7 is a timing diagram illustrating on/off statuses of the first switching element and the second switching element by a combined simultaneous/alternate lighting manner; and

FIG. 8 is a schematic view illustrating a LED module with a reduced operating temperature according to another preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

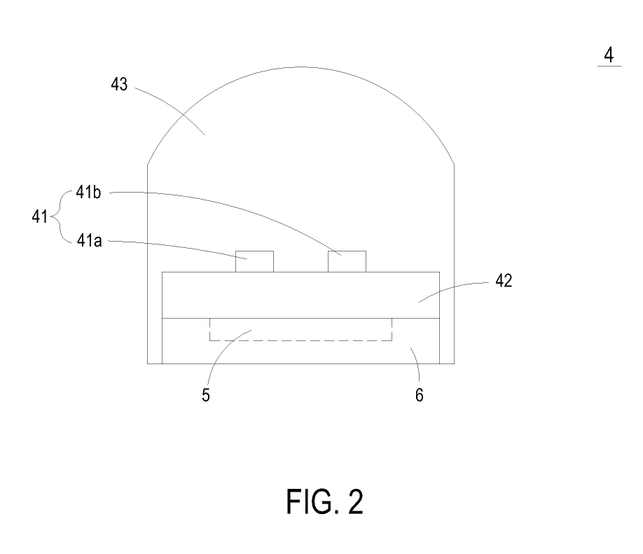

FIG. 2 is a schematic view illustrating a LED module with a reduced operating temperature according to a preferred embodiment of the present invention. The LED module 4 of FIG. 2 principally includes a plurality of LED chips 41, a substrate 42, a driving circuit 5, a carrier 6 and an encapsulant layer 43. The plurality of LED chips 41 are divided into a first LED chip set 41a and a second LED chip set 41b. The first LED chip set 41a and the second LED chip set 41b are disposed on the substrate 42 and electrically connected to the substrate 42. Depending on the composition of the semi-conducting material used for fabricating the LED chips 41, the color of the emitted light may be varied. Each of the first LED chip set 41a and the second LED chip set 41b includes at least one LED chip. The driving circuit 5 is formed in the carrier 6. The driving circuit 5 and the carrier 6 are coupled to the substrate 42 and electrically connected to the LED chips 41 through the substrate 42. The operations of the LED chips 41 are driven and controlled by the driving circuit 5. In accordance with a key feature of the present invention, the first LED chip set 41a and the second LED chip set 41b emit light in an alternate lighting manner or in a combined simultaneous/alternate lighting manner, thereby decreasing the operating temperature of the overall LED module 4. Furthermore, after the LED chips 41 are disposed on the substrate 42 and the driving circuit 5 and the carrier 6 are coupled to the substrate 42, the resulting structure are encapsulated with the encapsulant layer 43 to avoid physical damage or corrosion. Under this circumstance, the overall LED module 4 may emit light of a specified color such as blue light or red light.

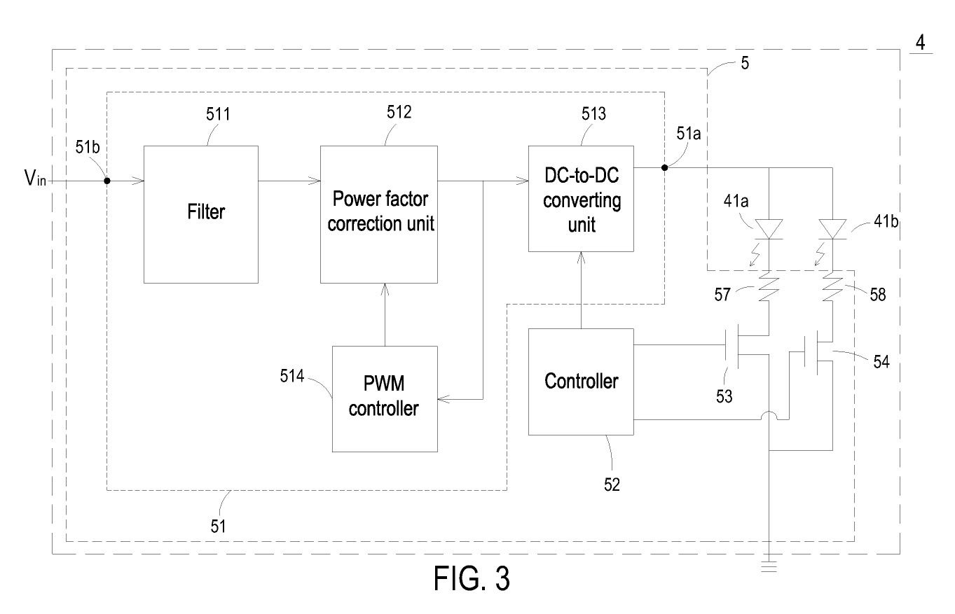

FIG. 3 is a circuit diagram illustrating an exemplary driving circuit 5 shown in FIG. 2 according to the present invention. The driving circuit 5 is used to drive the first LED chip set 41a and the second LED chip set 41b. The driving circuit 5 principally includes a power converting circuit 51, a controller 52, a first switching element 53 and a second switching element 54. An output terminal 51a of the power converting circuit 51 is coupled to the first LED chip set 41a and the second LED chip set 41b. By the power converting circuit 51, the input power Vᵢₙ is received and converted into a regulated output voltage or current required for the first LED chip set 41a and the second LED chip set 41b. In a case that the input power Vᵢₙ is alternating current, the power converting circuit 51 is a DC-to-DC converter for converting the input power Vᵢₙ into direct current required for the LED chips 41. The controller 52 is electrically connected to the power converting circuit 51, the first switching element 53 and the second switching element 54 for controlling on/off statuses of the first switching element 53 and the second switching element 54. In some embodiments, the controller 52 may control the magnitude of the voltage or current outputted from the power converting circuit 51 so as to adjust the brightness of the emitted light from the LED chips 41. The first switching element 53 is connected in series with the first LED chip set 41a and the output terminal 5 la of the power converting circuit 51. The second switching element 54 is connected in series with the second LED chip set 41b and the output terminal 51a of the power converting circuit 51.

In some embodiments, the driving circuit 5 further includes a first impedance element 57 (e.g. a first resistor) and a second impedance element 58 (e.g. a second resistor). The first impedance element 57 is connected in series with the first LED chip set 41a. The second impedance element 58 is connected in series with the second LED chip set 41b. By means of the first impedance element 57 and the second impedance element 58, the problem of causing instable brightness of emitted light due to temperature variations is alleviated.

In some embodiments, the power converting circuit 51 includes a filter 511, a power factor correction unit 512, a DC-to-DC converting unit 513 and a pulse width modulation (PWM) controller 514. The filtering unit 511 is interconnected between the input terminal 51b of the power converting circuit 51 and the power factor correction unit 512 for filtering the input power Vᵢₙ. The power factor correction unit 512 is interconnected between the filtering unit 511 and the DC-to-DC converting unit 513 for correcting the power factor of the power converting circuit 51 and converting the alternating voltage of the input power Vᵢₙ into a DC voltage, which is transmitted to the DC-to-DC converting unit 513. The DC-to-DC converting unit 513 is interconnected between the power factor correction unit 512 and the output terminal 51a of the power converting circuit 51 for converting the DC voltage into a regulated output voltage or current required for illuminating the first LED chip set 41a and the second LED chip set 41b. The PWM controller 514 is interconnected between the power factor correction unit 512 and the DC-to-DC converting unit 513 for controlling operations of the power factor correction unit 512.

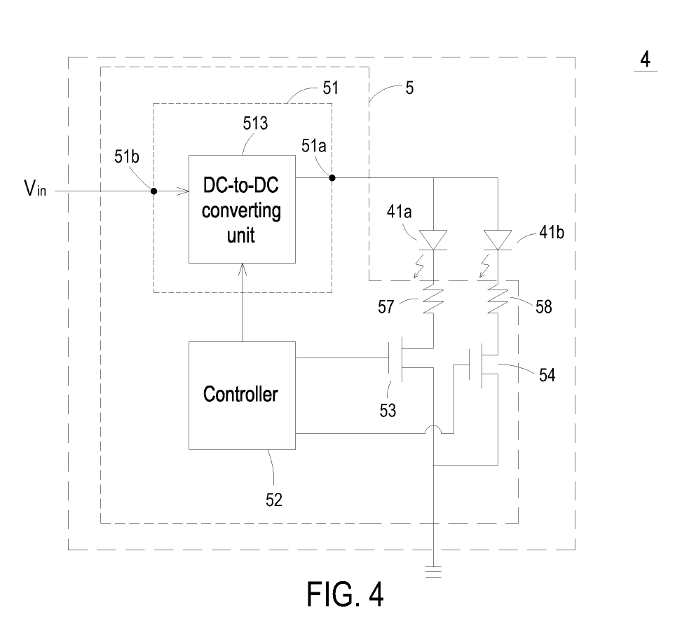

A further embodiment of a driving circuit is illustrated in FIG. 4. In this embodiment, the input power Vᵢₙ is a DC voltage and the power converting circuit 51 includes the DC-to-DC converting unit 513. The DC voltage of the input power Vᵢₙ is received and converted into a regulated output voltage or current required for illuminating the first LED chip set 41a and the second LED chip set 41b.

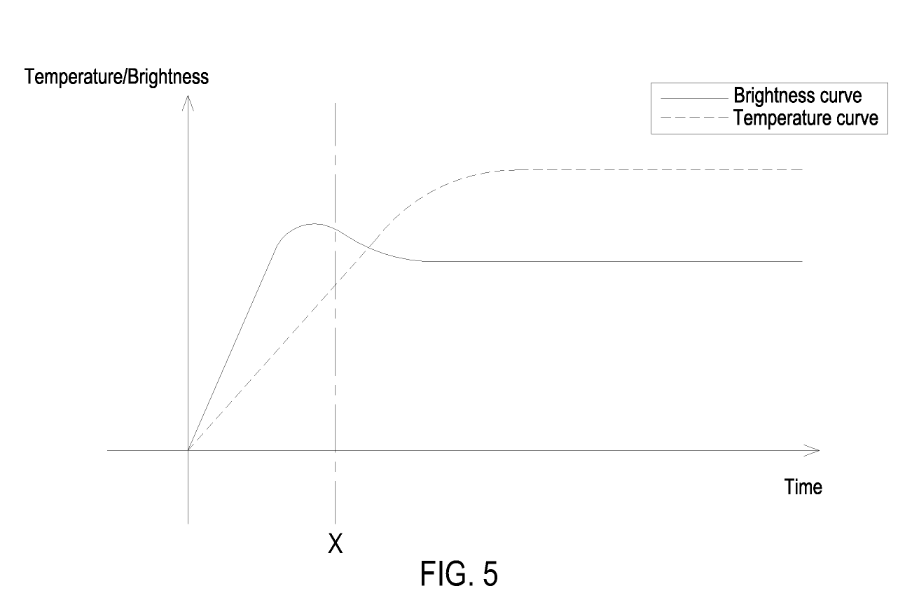

FIG. 5 is a characteristic plot showing the brightness and the operating temperature of a single LED chip as a function of operating time. As shown in the dotted curve of FIG. 5, the operating temperature of the LED chip is substantially in direct proportion to the operating time in the early stage. By an external heat-dissipation mechanism for example, the operating temperature of the LED chip is then maintained at an elevated temperature. On the other hand, the LED brightness reaches its maximum value in a shorter time period and is then slightly reduced to a specified value, as is indicated by the solid curve. In accordance with a key feature of the present invention, at least two LED chip sets emit light in an alternate lighting manner in order to reduce the operating time. As the operating time is reduced, the junction temperature of individual LED chips is lowered and thus the brightness of the light emitted from the overall LED module maintains at a desired level. For example, after the first LED chip set 41a illuminates for a certain time period X (e.g. 10 ms), the first LED chip set 41a is disabled while another LED chip set (e.g. the second LED chip set 41b) is enabled to emit light. According to such an alternate lighting manner, the operating time of individual LED chips is reduced, the junction temperature of individual LED chips is lowered and the brightness of the light emitted from the overall LED module maintains at a desired level.

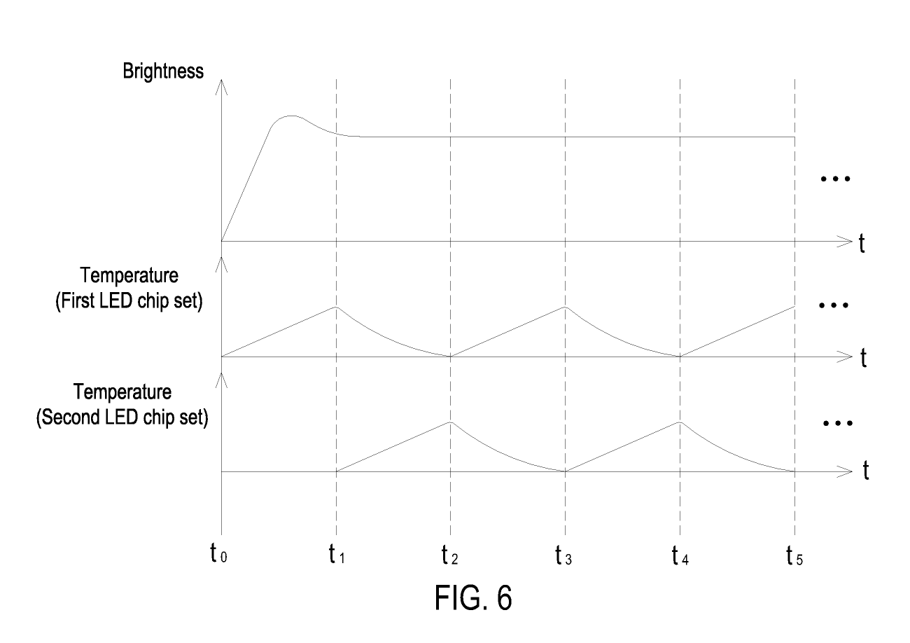

FIG. 6 is a graph showing the relationship between the brightness and the operating temperature of the first LED chip set 41a and the second LED chip set 41b as a function of operating time. The operation principles of the alternate lighting manner will be described in more details as follows with reference to FIGS. 3, 4 and 6.

At t=t₀, the driving circuit 5 is activated, and the controller 52 issues an enabling signal (e.g. a high-level voltage) to the first switching element 53. In response to the enabling signal, the first switching element 53 is turned on and thus the power converting circuit 51 transmits electricity to the first LED chip set 41a to illuminate the first LED chip set 41a. As the operating time elapses, the LED brightness gradually reaches to its maximum value and is then slightly reduced to a specified value. In the stage from t=t₀ to t=t₁, the operating temperature of the LED chip is substantially in direct proportion to the operating time. In other words, the operating temperature of the first LED chip set 41a is increased as the operating time is increased.

At t=t₁, the controller 52 issues an enabling signal to the second switching element 54 while issuing a disenabling signal (e.g. a low-level voltage) to the first switching element 53. In response to the enabling signal, the second switching element 54 is turned on and thus the power converting circuit 51 transmits electricity to the second LED chip set 41b to illuminate the second LED chip set 41b. Whereas, in response to the disenabling signal, the first switching element 53 is turned off to interrupt the illumination of the first LED chip set 41a. In the stage from t=t₁ to t=t₂, the brightness of the first LED chip set 41a is gradually decreased but the brightness of the second LED chip set 41b is gradually increased to be close to its maximum value. As a consequence, the brightness of the light emitted from the overall LED module 4 maintains at a desired level of nearly the maximum value. Moreover, in the stage from t=t₁ to t=t₂, the operating temperature of the second LED chip set 41b is gradually increased but the operating temperature of the first LED chip set 41a is gradually decreased. As a consequence, the operating temperature of the overall LED module 4 maintains at an acceptable level.

Similarly, in the stage from t=t₂ to t=t₃, the first LED chip set 41a is controlled by the controller 52 to emit light but the illumination of the second LED chip set 41b is interrupted. In the stage from t=t₃ to t=t₄, the first LED chip set 41a is controlled by the controller 52 to interrupt illumination but the second LED chip set 41b is controlled to emit light. In the stage from t=t₄ to t=t₅, the first LED chip set 41a is controlled by the controller 52 to emit light but the illumination of the second LED chip set 41b is interrupted. The rest may be deduced by analog. Accordingly, by alternately lighting the first LED chip set 41a and the second LED chip set 41b, the brightness of the light emitted from the overall LED module 4 maintains at a desired level, which is substantially equal to the brightness of the light emitted from a single LED chip set. More especially, the operating temperature of the overall LED module 4 may be reduced to approximately a half of the operating temperature of a single LED chip set.

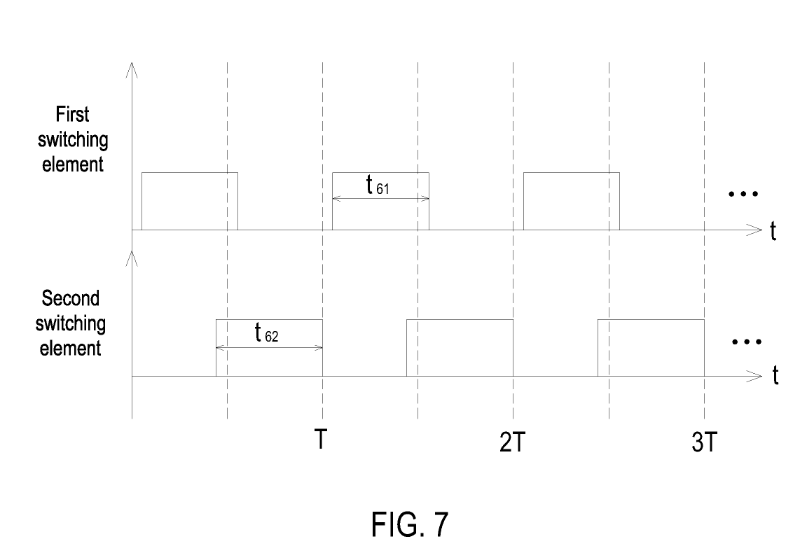

In the above embodiments, the first switching element 53 and the second switching element 54 are controlled by the controller 52 to be alternatively turned on or turned off, so that the first LED chip set 41a and the second LED chip set 41b can emit light in an alternate lighting manner. It is noted that, however, those skilled in the art will readily observe that numerous modifications and alterations of the lighting manner may be made while retaining the teachings of the invention. For example, the on/off statuses of the first switching element 53 and the second switching element 54 may be partially overlapped with each other, as can be seen in FIG. 7. For each cycle period T, the on duration of the first switching element 53 is t₆₁ and the on duration of the second switching element 54 is t₆₂. In some time intervals, the on/off statuses of the first switching element 53 and the second switching element 54 are partially overlapped with each other. Whereas, in the remaining time intervals, the first switching element 53 and the second switching element 54 are alternatively turned on or turned off, so that the first LED chip set 41a and the second LED chip set 41b can emit light in an alternate lighting manner. Moreover, the first LED chip set 41a is operated at a duty cycle of t₆₁/T and the second LED chip set 41b is operated at a duty cycle of t₆₂/T. Alternatively, the duty cycles of the first LED chip set 41a and the second LED chip set 41b may be identical or different according to the performance requirements. In the context of the present invention, the lighting manner as shown in FIG. 7 is also referred as a combined simultaneous/alternate lighting manner.

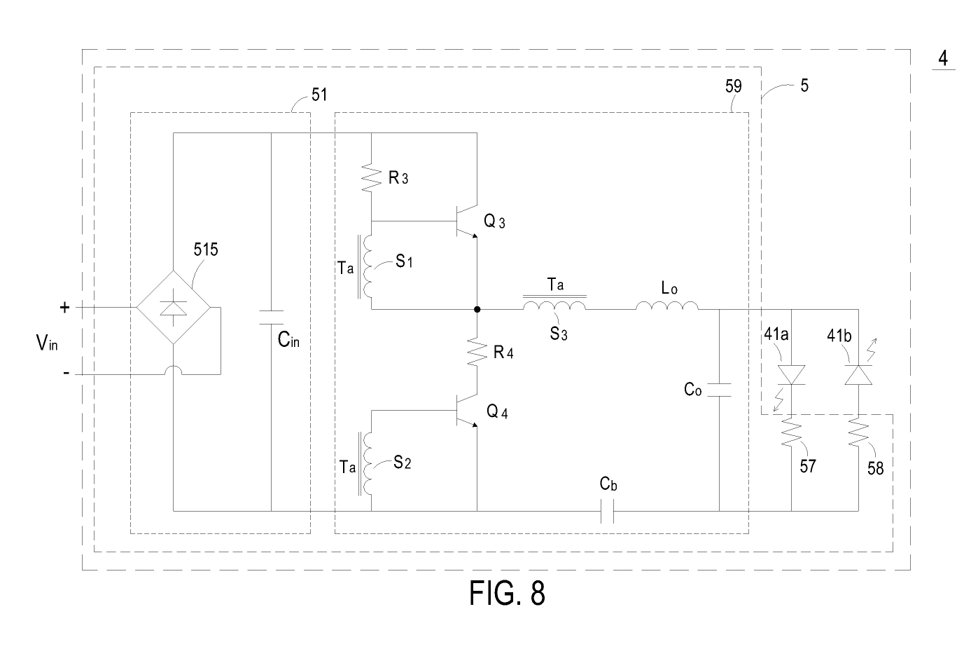

In the above embodiments, the driving circuit 5 is implemented in a digital form. Nevertheless, the driving circuit of the present invention may be implemented in an analog form. FIG. 8 is a circuit diagram illustrating an exemplary driving circuit implemented in an analog form. The driving circuit 5 includes a power converting circuit 51 and a waveform generator 59. The power converting circuit 51 is electrically connected to the waveform generator 59. After the input power Vᵢₙ is received by the power converting circuit 51, the input power Vᵢₙ is converted and transmitted to the waveform generator 59. The output terminal of the waveform generator 59 is connected to the first LED chip set 41a and the second LED chip set 41b. By the waveform generator 59, a control wave with positive and negative voltages is generated. An example of the control wave includes but is not limited to a rectangular wave, a square wave and the like. The positive and negative voltages of the control wave are used to drive the first LED chip set 41a and the second LED chip set 41b, respectively.

In this embodiment, the directions of the current passing through the first LED chip set 41a and the second LED chip set 41b are opposed to each other. During a certain interval, only one of the first LED chip set 41a and the second LED chip set 41b is turned on to emit light. For example, the first LED chip set 41a is turned on to emit light in response to the positive voltage of the control wave outputted from the waveform generator 59, but the second LED chip set 41b is turned on to emit light in response to the negative voltage of the control wave outputted from the waveform generator 59. As the control wave with positive and negative voltages is continuously generated from the waveform generator 59, the first LED chip set 41a and the second LED chip set 41b emit light in an alternate lighting manner. In some embodiments, a transient zero voltage is intervened between the positive and negative voltages. During the time interval corresponding to the zero voltage, the first LED chip set 41a and the second LED chip set 41b both interrupt illumination. In some embodiments, the durations of the positive voltage and the negative voltage may be identical or varied according to the performance requirement of respective LED chip sets.

In some embodiments, the driving circuit 5 further includes a first impedance element 57 (e.g. a first resistor) and a second impedance element 58 (e.g. a second resistor). The first impedance element 57 is connected in series with the first LED chip set 41a. The second impedance element 58 is connected in series with the second LED chip set 41b. By means of the first impedance element 57 and the second impedance element 58, the problem of causing instable brightness of emitted light due to temperature variations is alleviated.

Please refer to FIG. 8 again. The power converting circuit 51 includes a rectifier 515 and an input capacitor Cᵢₙ. The input power Vᵢₙ is rectified into DC power by the rectifier 515. The noise contained in the DC power is filtered off by the input capacitor Cᵢₙ, thereby generating a suitable voltage or current required for the waveform generator 59.

Furthermore, the waveform generator 59 includes a third switching element Q₃, a fourth switching element Q₄, a transformer Tₐ, a third resistor R₃, a fourth resistor R₄, an output inductor Lₒ, an output capacitor Cₒ and a second capacitor C_{b}. The emitter of the third switching element Q₃ is coupled to the fourth resistor R₄, the first winding coil S₁ and the third winding coil S₃ of the transformer Tₐ. The base of the third switching element Q₃ is coupled to the third resistor R₃ and the first winding coil S₁ of the transformer Tₐ. The collector of the third switching element Q₃ is coupled to the positive end of the power converting circuit 51. The emitter of the fourth switching element Q₄ is coupled to the negative end of the power converting circuit 51. The base of the fourth switching element Q₄ is coupled to the second winding coil S₂ of the transformer Tₐ. The collector of the fourth switching element Q₄ is coupled to the fourth resistor R₄. The output capacitor Cₒ is coupled to the output terminal of the waveform generator 59 and connected in series with the output inductor Lₒ, the second capacitor C_{b} and the third winding coil S₃ of the transformer Tₐ.

In this embodiment, when the third switching element Q₃ is turned on but the fourth switching element Q₄ is turned off, a close loop is defined by the third switching element Q_{3,} the third winding coil S₃ of the transformer Tₐ, the output inductor Lₒ, the output capacitor Cₒ and the second capacitor C_{b}, so that a positive voltage is outputted from the waveform generator 59 to illuminate the first LED chip set 41a. Whereas, when the third switching element Q₃ is turned off but the fourth switching element Q₄ is turned on, a close loop is defined by the fourth switching element Q₄, the third winding coil S₃ of the transformer Tₐ, the output inductor Lₒ, the output capacitor Cₒ and the second capacitor C_{b}, so that a negative voltage is outputted from the waveform generator 59 to illuminate the second LED chip set 41b. Accordingly, the first LED chip set 41a and the second LED chip set 41b emit light in an alternate lighting manner, thereby decreasing the operating temperature of the overall LED module 4.

In the above embodiments, the driving circuit 5 is mounted on the carrier 6. Alternatively, some components of the driving circuit 5 are mounted on the carrier 6 but the remaining components are formed on a system circuit board (not shown) which the overall LED module 4 is mounted on.

From the above description, the LED module of the present invention is formed by encapsulating a plurality of LED chips, a substrate and the carrier having a driving circuit. According to an alternate lighting manner, the operating time of individual LED chips is reduced and the junction temperature of individual LED chips is lowered. As a consequence, the illuminating efficiency of the overall LED module is increased and the brightness of the light emitted from the overall LED module maintains at a desired level. Since the problems encountered from the conventional heat-dissipation mechanisms are overcome, the LED module of the present invention is advantageous in the aspects of heat-dissipating efficiency and cost-effectiveness.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A LED module with a reduced operating temperature, said LED module comprising:
a substrate;
a plurality of LED chips disposed on said substrate and electrically connected to said substrate, wherein said plurality of LED chips are divided into a first LED chip set and a second LED chip set;
a carrier coupled to the substrate and having a driving circuit, said driving circuit being electrically connected to said plurality of LED chips for driving operations of said plurality of LED chips, wherein said first LED chip set and said second LED chip set emit light in an alternate lighting manner or in a combined simultaneous/alternate lighting manner so as to reduce the operating temperature of said LED module; and
an encapsulant layer covering said plurality of LED chips, said substrate and said carrier having said driving circuit.

2. The LED module according to claim 1 wherein said LED chips are single-color LED chips for emitting light of the same color.

3. The LED module according to claim 1 wherein said driving circuit further comprises:
a power converting circuit electrically connected to said first LED chip set and said second LED chip set for receiving an input power and converting said input power into a regulated output voltage or current required for illuminating said first LED chip set and said second LED chip set;
a plurality of switching elements electrically connected to said first LED chip set and said power converting circuit; and
a controller electrically connected to said switching elements for controlling alternate or combined simultaneous/alternate switching on/off statuses of said switching elements, so that said first LED chip set and said second LED chip set emit light in said alternate lighting manner or said combined simultaneous/alternate lighting manner.

4. The LED module according to claim 3 wherein each of said first LED chip set and said second LED chip set includes at least one LED chip.

5. The LED module according to claim 3 wherein said switching elements include:
a first switching element electrically connected to said first LED chip set and said power converting circuit; and
a second switching element electrically connected to said second LED chip set and said power converting circuit.

6. The LED module according to claim 5 wherein said first switching element and said second switching element controlled by said controller have identical or different duty cycles.

7. The LED module according to claim 5 wherein said driving circuit further includes:
a first impedance element connected in series with said first LED chip set; and
a second impedance element connected in series with said second LED chip set.

8. The LED module according to claim 5 wherein said power converting circuit includes:
a filter electrically connected to an input terminal of said power converting circuit for filtering said input power;
a power factor correction unit electrically connected to said filter for correcting the power factor of said power converting circuit and converting said input power;
a DC-to-DC converting unit interconnected between said power factor correction unit and an output terminal of said power converting circuit for converting said corrected input power into said regulated output voltage or current required for illuminating said first LED chip set and said second LED chip set; and
a pulse width modulation controller interconnected between said power factor correction unit and said DC-to-DC converting unit for controlling operations of said power factor correction unit.

9. The LED module according to claim 5 wherein said power converting circuit includes a DC-to-DC converting unit for directly receiving said input power and converting said input power into said regulated output voltage or current required for illuminating said first LED chip set and said second LED chip set.

10. The LED module according to claim 1 wherein said first LED chip set and said second LED chip set are electrically connected to said driving circuit, and said driving circuit includes:
a power converting circuit for receiving an input power and converting said input power into a regulated output voltage or current required for illuminating said first LED chip set and said second LED chip set; and
a waveform generator electrically connected to said power converting circuit and said first LED chip set and said second LED chip set for generating a control wave with positive and negative voltages, wherein said first LED chip set and said second LED chip set emit light in said alternate lighting manner in response to said positive and negative voltages of said control wave.

11. The LED module according to claim 10 wherein said control wave is continuously generated from said waveform generator.

12. The LED module according to claim 10 wherein said driving circuit further includes:
a first impedance element connected in series with said first LED chip set; and
a second impedance element connected in series with said second LED chip set.

13. The LED module according to claim 10 wherein said power converting circuit includes:
a rectifier for rectifying said input power; and
an input capacitor for filtering off noise and generating a voltage or current required for said waveform generator.

14. The LED module according to claim 10 wherein said waveform generator includes a plurality of switching elements, which are alternatively conducted or shut off, so that said first LED chip set and said second LED chip set emit light in said alternate lighting manner.
